(19) United States
(12) Patent Application Publication
(10) Pub. No.: US 2024/0393185 A1
(43) Pub. Date: Nov. 28, 2024

(54) MEASURING ASSEMBLY

(71) Applicant: EBM-PAPST MULFINGEN GMBH & CO. KG, Mulfingen (DE)

(72) Inventors: Sebastian SCHROTH, Kupferzell (DE); Sébastian HEINI, Urmatt (FR)

(21) Appl. No.: 18/694,755

(22) PCT Filed: Sep. 15, 2022
(86) PCT No.: PCT/EP2022/075696

§ 371 Date: Mar. 22, 2024

(30) Foreign Application Priority Data
Sep. 23, 2021 (DE) 10 2021 124 678.4

(51) Int. Cl. G01K 7/16

(52) U.S. Cl. CPC G01K 7/16

(57) ABSTRACT

The invention disclosure relates to a measuring assembly for measuring a parameter on an electrical device, in particular an electric motor. The electrical device is controlled by means of an inverter circuit. The measuring assembly has a measuring circuit which is electrically connected, by means of a measuring line, to a sensor unit having at least one sensor output of the inverter circuit. At least two different inverter output potentials can be applied to the control line depending on the switching state of the inverter output or of the inverter circuit. The measuring circuit is designed to transmit an output signal to the sensor unit and to detect and electrical measurement variable on the measuring line and/or the control line. On the basis of the received output signal, the sensor unit influences the electrical measurement variable depending on the parameter to be detected, for example the temperature. For example, for this purpose the sensors may have a parameter-dependent resistor.

### CROSS REFERENCE TO RELATED APPLICATIONS

This application is a National Stage of PCT Application No. PCT/EP2022/075696 filed on Sep. 15, 2022, which claims priority to German Patent Application No. 10 2021 124 678.4 filed on Sep. 23, 2021, the contents each of which are incorporated herein by reference thereto.

### TECHNICAL FIELD

The present disclosure refers to a measuring assembly for an electrical device that can be controlled by means of an inverter circuit. For example, the electrical device can be an electric motor, particularly a brushless direct current electric motor (BLDC). The application is in general also suitable for other types of electrical machines, such as synchronous machines or also for other technical fields, for example luminaires in which the luminaire control comprises an inverter circuit.

### BACKGROUND

The measuring assembly comprises one or more sensors assigned to the electrical device in order to detect a parameter to be measured there, such as the temperature, an acceleration in one or more spatial directions, a humidity parameter describing the humidity of the surrounding atmosphere, etc.

DE 10 2016 106 431 A1 describes a measuring assembly comprising multiple two-terminal circuits having a capacitance and a temperature-dependent impedance respectively, which are connected in parallel to the motor cores in an electric motor. The electric motor is controlled by means of a frequency converter. Additional lines for connecting the two-terminal circuits are therefore not necessary. The current response during switching on the current through one of the motor cores is influenced in a temperature-dependent manner by means of the temperature-dependent impedance of the two-terminal circuit connected in parallel to the motor core and can be evaluated in order to determine the temperature at the installation position of the two-terminal circuit.

A method is known from DE 10 2014 005 706 A1 in which the respective current temperature is calculated based on an initial temperature by means of a model.

DE 197 43 046 C1 proposes to determine the motor current and the motor voltage for temperature detection of an electric motor and to determine the active component of the motor impedance therefrom. Based on a known correlation between the active component of the motor impedance and the temperature (for example measured reference values), the temperature determination can then be carried out. A similar method is also described in DE 196 30 027 A1 in which also a winding of the electric motor is directly used as temperature sensor for measurement of the voltage and the current.

### BRIEF SUMMARY

Starting from the prior art it is the object of the present disclosure to provide a measuring assembly with one or more sensors, which guarantees low installation efforts on one hand and makes an independent evaluation of each present sensor possible on the other hand.

Disclosed is a measuring assembly for an electrical device that is controlled by means of an inverter circuit, including: a control line connected with an inverter output of inverter circuit, at which an inverter output potential applies, which is predefined by the inverter circuit, a measuring circuit that is connected with a sensor unit via a measuring line and in addition with the control line and that is configured to transmit an output signal via the measuring line to the sensor unit and that is in addition configured to detect an electrical measured parameter at the measuring line and/or the control line, wherein the sensor unit comprises at least one sensor, which is configured for arrangement on or in the electrical device, wherein the at least one sensor is arranged in an electrical path between the measuring line and the control line and is configured to influence the output signal depending on a parameter to be measured.

The measuring assembly serves to detect a parameter, for example a temperature, a humidity of a surrounding atmosphere, an acceleration in at least one spatial direction or another physical parameter or an arbitrary combination of multiple of the indicated parameters on or in an electrical device. The electrical device is controlled by means of an inverter circuit and can be an electrical machine, particularly an electric motor, for example. In one example, the electric motor is a brushless direct current electric motor (BLDC). Preferably the inverter circuit is configured to create a circulating stator magnetic field.

The inverter circuit has at least one inverter output, which is used for the measuring assembly. Depending on the number of the phases of the electrical device to be controlled, the inverter circuit can also comprise multiple inverter outputs of which particularly one single inverter output is used for the measuring assembly. The measuring assembly is electrically connected with a control line. Depending on the switching condition of the inverter circuit, different inverter output potentials can be applied on the control line, for example a supply voltage potential or a ground potential. When switching the inverter circuit, the potential on the inverter output changes and thus also on the control line, which is therefore not connected to a fixed reference potential.

The measuring assembly comprises a measuring circuit. One connection of the measuring circuit is connected to the control line of the used inverter output. Thus, the inverter output potential is submitted to the measuring circuit.

In addition, the measuring circuit is connected with a sensor unit by means of a measuring line. The measuring line and the control line are only indirectly connected to one another by means of the measuring circuit or the sensor unit and can thus have different voltage potentials.

The measuring circuit is configured to apply an output signal to the measuring line and to transmit it via the measuring line to the sensor unit. Preferably, the output signal is an output current defined by the measuring circuit. The output current is particularly not constant, but comprises varying current values. Particularly, the output signal is a periodic signal, for example a sinusoidal signal. The period or frequency of the output signal can be constant in some embodiments and can vary in other embodiments.

The measuring circuit is in addition configured to detect an electrical measured parameter on the measuring line and/or the control line. In an embodiment a measured voltage between the measuring line and the control line is detected as measured parameter.

The sensor unit comprises at least one sensor. The sensor is assigned to the electrical device and configured for arrangement on or in the electrical device. Preferably, the sensor unit is configured entirely for arrangement on or in the electrical device and can be arranged on a common support, for example a circuit board. Each sensor of the sensor unit is arranged in an electrical path between the measuring line and the control line and configured to influence the output signal received via the measuring line depending on a parameter to be measured. For example, the sensor can be an electrical resistor, which changes its resistance value depending on the parameter to be measured, for example depending on the temperature, the humidity, etc. In doing so, the measured voltage may vary depending on the current resistance value, for example. Alternatively to this, the sensor unit can also be configured to modify, for example modulate, the output signal in a parameter-dependent manner in order to produce the measured parameter. Thereby all known kinds of modulation can be used. The measuring circuit can determine the parameter detected by the at least one sensor by means of a corresponding demodulation.

The measuring assembly particularly comprises only one (single pole) measuring line between the measuring circuit and the sensor unit. In addition to the connections that are provided anyway between the inverter circuit and the electrical device, only one additional single pole connection is required for the measuring line. Therefore, the installation effort is low. In addition, for connection of the sensor unit the anyway existing control line of the inverter circuit is used. Because the modulator and the demodulator are referred to the potential of the control line, a changing inverter output potential has no direct influence on the measuring circuit. Therefore, the measuring circuit can determine the parameter to be measured reliably despite of the changing inverter output potential.

The measuring assembly described above uses only one single inverter output connected to the control line. However, multiple measuring assemblies operating independent from one another can also be used in which multiple inverter outputs are connected with one measuring circuit and one sensor unit respectively, for example, as described above. It is in addition possible to connect multiple measuring circuits with multiple sensor units to one inverter output. Also, it is possible to connect multiple sensor units to one measuring circuit. Two or more of the above-described variations can be realized in arbitrary combination with each other.

In a preferred embodiment a sensor unit comprises at least two sensors and a coupling device. The coupling device is arranged in an electrical path between the sensors and the measuring line. It is configured to transmit the output signal depending on a characteristic of the output signal to one or more defined sensors of a sensor group. The transmission of the output signal to at least one other sensor is inhibited by means of the coupling device. In this manner the measuring circuit can specifically select one sensor or a defined sensor group by means of adaption of the characteristic of the output signal and can determine the parameter based on the measurement by means of this sensor or this sensor group. For example, the sensors of the sensor unit can be arranged at different locations on or in the electrical device, so that by means of selection of the sensors arranged at different locations, the parameter can be determined in a position-dependent manner. Thus, in one embodiment the temperature, the humidity, etc. can be determined at different locations of the electrical device or the electric motor.

The characteristic of the output signal that can be evaluated by means of the coupling device can be the polarity of the output signal and/or the frequency of the output signal and/or the absolute value of the output signal.

In a preferred embodiment the coupling device comprises passive components only, i.e. non-controllable and/or non-amplifying components.

In an embodiment the sensor unit has exactly two sensors, namely a first sensor and a second sensor. Thereby the coupling device can comprise a first blockable component, for example a first diode, and a second blockable component, for example a second diode. The first blockable component and the first sensor form a first series connection and the second blockable component and the second sensor form a second series connection. The two series connections are connected in parallel to each other between the measuring line and the control line. If diodes are used as blockable components, the diodes of the coupling device are electrically connected in opposite forward biased direction relative to one another. For example, the cathode of the first diode is electrically connected to the first sensor and the anode of the second diode is electrically connected to the second sensor. In this arrangement a current can either flow through the first sensor or the second sensor depending on the polarity of the output signal.

If instead of the passive diodes actively controlled and blockable components are used, for example transistors or thyristors, the sensor unit can also comprise more than two selectable sensors or sensor groups.

If the coupling device comprises diodes as means for selecting of one of the connected sensors, it is advantageous if the output signal can have different polarities. For example, the output signal can be a periodic output signal having alternating polarities, for example a sinusoidal output signal, a triangular output signal, a square wave output signal, etc. In other configurations of the coupling device the periodic output signal can also continuously have the same polarity (positive or negative, in each case inclusive or exclusive zero).

In an embodiment of the measuring assembly the coupling device comprises a crossover network. For example, the crossover network can be formed by one or more filters, for example at least one high pass and/or at least one low pass and/or at least one band pass. In this case the output signal can be created having different frequencies, so that one or more sensors can be selected and used for determination of the parameter to be measured depending on the frequency of the output signal.

In another embodiment of the measuring assembly, the measuring line and the control line are part of a bus line. For example, the bus line can be configured according to a defined standard, for example I²C-standard. Each sensor of the sensor unit can then be selected or used by means of a filter arrangement of the coupling device, wherein the filter arrangement passes the output signal to a sensor or blocks it depending on its characteristic.

It is advantageous, if the measuring circuit comprises a voltage supply in the type of a bootstrap voltage supply, which is connected to the control line. Particularly, the bootstrap voltage supply comprises a capacitor connected between a voltage supply line and the control line. Depending on the switching condition of the inverter circuit and thus from the inverter output potential on the control line, the capacitor can buffer energy for operation of the measuring circuit.

Preferably the measuring circuit comprises a measuring output at which a measuring signal is provided. The measuring signal is based on the measured parameter detected by the measuring circuit. Particularly, the measuring signal is independent from the potential of the inverter output potential on the control line. The measuring signal is potential free so-to-speak.

In an embodiment the measuring output can be separated galvanically from the control line and/or the measuring line and/or the remaining part of the measuring circuit. The galvanic separation is preferably realized by means of an optocoupler.

The measuring output can be configured as blank transistor output, for example as so-called open collector output (OC) or as open drain output (OD).

In the voltage or energy-free condition of the measuring circuit the measuring signal applied at the measuring output corresponds to a condition indicating exceedance of a limit value for the parameter to be measured, for example the exceedance of a limit temperature, if the at least one sensor is used for temperature measurement. In doing so, it can be guaranteed that in case of a defect, for example when the voltage supply of the measuring circuit fails or in case of a defect in the control of the measuring output, no safety critical condition of the monitored electrical device is allowed.

In each of the described embodiments it is advantageous, if the measuring circuit is arranged on a circuit board together with the inverter. It is in addition advantageous, if the inverter and the measuring circuit are arranged in a common housing independent from whether they are built on a common circuit board or individual circuit boards. This has the advantage that the control line does not have to be configured separately, but corresponds directly to the control line.

In addition, in all of the embodiments described above it can be advantageous, of the potential of the voltage source supplying the measuring circuit is related to the same ground potential as the inverter. Therefrom a well-arranged circuit configuration results.

### BRIEF DESCRIPTION OF THE DRAWINGS

Advantageous embodiments of the present disclosure are derived from the dependent claims, the description and the drawing. In the following preferred embodiments of the present disclosure are described in detail based on the attached drawing. The drawing shows:

FIG. 1 a block diagram of an electrical device in the form of an electric motor controlled by means of an inverter circuit as well as a measuring assembly assigned to the electric motor,

FIG. 2 a block diagram of an embodiment of the measuring assembly from FIG. 1,

FIGS. 3 to 5 a block diagram of an embodiment for a sensor unit of the measuring assembly from FIG. 2 in each case and

FIG. 6 a block diagram of an alternative embodiment of the measuring assembly comprising a bus line to which the sensor unit is connected,

FIGS. 7 and 8 exemplary illustrations of a time-dependent progress of an output signal respectively that the measuring circuit supplies to the sensor unit.

### DETAILED DESCRIPTION

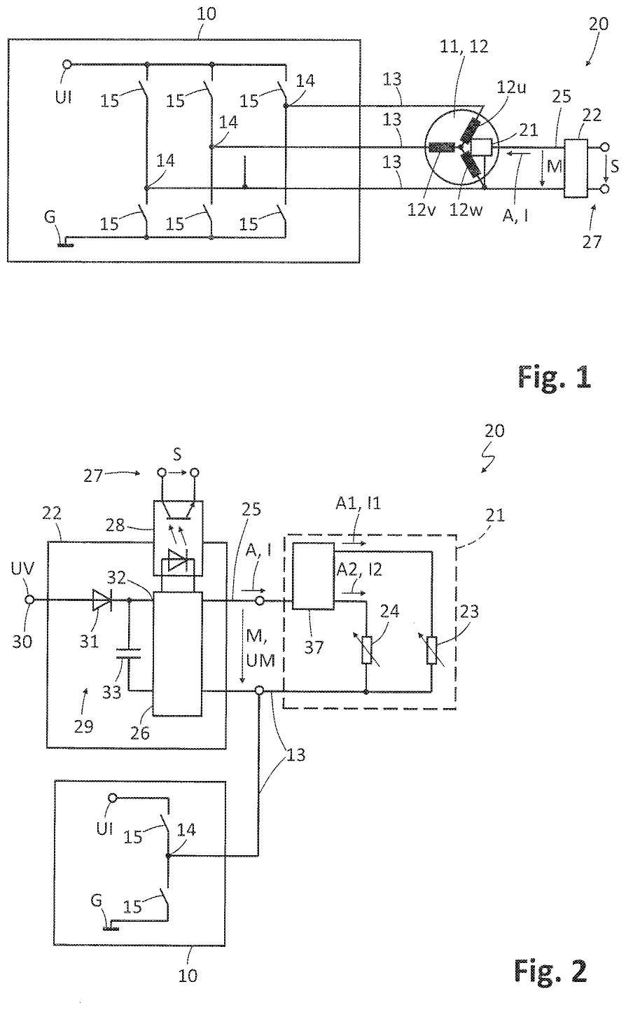

FIG. 1 is a block diagram of an electrical device 11 controlled by an inverter circuit 10, wherein the electrical device 11 is an electric motor 12, particularly a brushless DC electric motor, in the example illustrated in FIG. 1. According to the example, the electric motor 12 has three motor phases 12u, 12v, 12w, wherein each motor phase 12u, 12v, 12w is connected to one assigned inverter output 14 of inverter circuit 10 respectively by means of a separate control line 13. Depending on the number of motor phases to be controlled, the inverter circuit 10 has a corresponding number of individually controllable inverter outputs 14.

The inverter circuit 10 has multiple controllable inverter switches 15. In the embodiment each inverter output 14 is arranged between two inverter switches 15 connected in series. Depending on which of the two serially connected inverter switches 15 is closed, each inverter output 14 can either be connected with an inverter voltage UI provided to the inverter circuit 10 or alternatively with ground G. Only one of the inverter switches 15 connected in series and connected to a common inverter output 14 is conductive, while the respective other inverter switch 15 blocks. At each inverter output 14 or at each control line 13, therefore, the inverter voltage UI or alternatively ground potential of ground G can be applied as inverter output potential. The inverter output potential at control line 13 is thus not constant, but changes depending on the switching condition of the inverter circuit 10.

A measuring assembly 20 comprising a sensor unit 21 and a measuring circuit 22 is connected to one of the control lines 13. The measuring assembly 20 could also have multiple groups of one sensor unit 21 and one measuring circuit 22 respectively, which are connected with one separate control line 13 respectively. The measuring assembly 20 is configured to measure a parameter on or in the electrical device 11 or the electric motor 12 by means of the sensor unit 21, for example a temperature, a humidity of the surrounding atmosphere, an acceleration in at least one spatial direction, a current, a voltage, etc. or an arbitrary combination thereof. For this purpose, sensor unit 21 comprises at least one sensor, preferably multiple sensors and in the embodiment a first sensor 23 and a second sensor 24.

The sensors 23, 24 can be arranged on a common support, for example a circuit board. The support and/or the sensors 23, 24 are preferably in heat-conducting connection with the winding of at least one of the motor phases 12u, 12v, 12w, for example in direct contact, as only highly schematically illustrated in FIG. 1. This is advantageous in the embodiment, because the sensor unit 21 is preferably configured to detect at least one temperature value of at least one winding of at least one of the motor phases 12u, 12v, 12w. The sensors 23, 24 can be in heat-conducting connection with different windings or different motor phases. For temperature detection in general, the at least one sensor 23, 24 is arranged at a location in or on the electrical device 11 (here: electric motor 12) at which the temperature shall be detected.

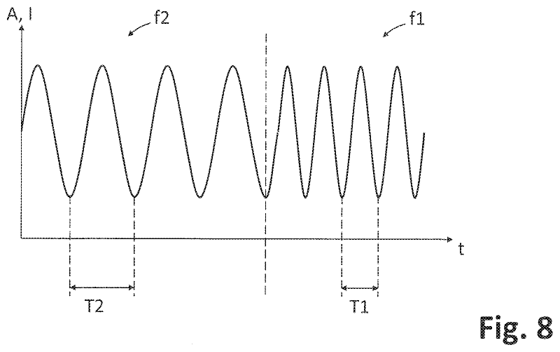

The measuring circuit 22 is connected with sensor unit 21 by means of a measuring line 25 and can transmit an output signal A to the sensor unit 21 via measuring line 25. The output signal A can be an output current I, which is defined by measuring circuit 22. The output signal A is preferably not constant, but has temporally changing progress, for example a periodic progress, as illustrated in the embodiments according to FIGS. 7 and 8. The output signal A and according to the example the defined output current I can have at least one characteristic or feature, which can be evaluated by sensor unit 21 or which results in different effects or conditions in sensor unit 21. This characteristic can be, for example, the polarity of the output signal, as it is depicted by way of example in FIG. 7. In another embodiment the characteristic can be the frequency of the output signal A (FIG. 8). Also, another modifiable parameter, such as an absolute value or the amplitude of the output signal, a flank progress (increasing or decreasing), a flank steepness, etc. can be used as characteristic alternatively or additionally for influencing sensor unit 21.

In the embodiment output signal A or output current I has a time-varying amount and can be a periodic signal, for example. In FIGS. 7 and 8 a sinusoidal progress is illustrated by way of example as periodic signal. Also, other signal progresses, for example a square wave signal, a triangular signal, a sawtooth signal, etc. can be used. The signal shape of output signal A can principally be arbitrarily selected.

An embodiment of measuring assembly 20 is illustrated in FIG. 2, wherein only one of the inverter outputs 14 of inverter circuit 10 is illustrated, which is used for measuring assembly 20. In the embodiment sensor unit 21 has multiple sensors and according to the example, a first sensor 23 and a second sensor 24. The sensors 23, 24 are connected via a coupling device 37 with measuring line 25. The coupling device 37 is, therefore, arranged in the electrical path between measuring line 25 and sensors 23, 24. The coupling device 37 is configured to transmit the output signal A or the output current I as first output signal A1 or first output current I1 to the first sensor 23 or to transmit the output signal A or the output current I as second output signal A2 or second output current I2 to the second sensor 24, depending on the characteristic of output signal A and according to the example of output current I. Thus, depending on the set characteristic of output signal A, the determination of the parameter to be detected can be carried out by means of first sensor 23 or by means of second sensor 24. Preferably, at each point in time the output signal A is only transmitted by means of coupling device 37 to one of the connected sensors 23 or 24. The coupling device 37 can form a kind of separating filter or switch, so-to-speak, which changes its condition based on the characteristic of output signal A.

The measuring circuit 22 is configured to detect an electrical measured parameter M at measuring line 25 and/or a control line 13, according to the example a measured voltage UM between measuring line 25 and control line 13. Based on the electrical measured parameter M, measuring circuit 22 produces a measuring signal S that is provided at a measuring output 27 of measuring circuit 22. The measuring output 27 is preferably configured as blank transistor output, for example as open collector output or alternatively as open drain output depending on the configuration of the transistor (bipolar transistor or field effect transistor).

An evaluation unit 26 of measuring circuit 22 is connected with measuring line 25 as well as control line 13 and serves for creation of output signal A as well as for detection of electrical measured parameter M. In the embodiment it is also configured to provide measuring signal S at a measuring output 27 of measuring circuit 22.

The measuring signal S can be an analog signal or a digital signal. For example, measuring signal S can indicate the electrical measured parameter M by means of an analog value or by means of a modulation, for example a pulse width modulation.

The measuring output 27 is preferably galvanically separated from evaluation unit 26, measuring line 25 and control line 13. For galvanic separation an optocoupler 28 can be used, for example. A light emitting diode of optocoupler 28 is connected with evaluation unit 26 of measuring circuit 22 and is controlled by evaluation unit 26 depending on the electrical measured parameter M and according to the example, the measured voltage UM.

The measuring circuit 22 comprises in addition an internal voltage supply to which an external supply voltage UV is applied. The voltage supply of measuring circuit 22 is configured as bootstrap voltage supply 29 in the embodiment.

The bootstrap voltage supply comprises a supply connection 30 for applying the supply voltage UV, which is connected via an input diode 31 with an input 32 of evaluation unit 26. Thereby anode of input diode 31 is connected with supply connection 30 and the cathode of input diode 31 is connected with input 32.

According to the example, a buffer capacitor 33 of bootstrap voltage supply 29 is connected between input 32 and control line 13. The buffer capacitor 33 can store electrical energy for supply of evaluation unit 26. The buffer capacitor 33 is loaded, if inverter output potential at control line 13 corresponds to ground potential of ground G. If inverter output potential at control line 13 corresponds to the inverter voltage UI, the evaluation unit 26 can take electrical energy out of buffer capacitor 33 for operation. By means of input diode 31, it is avoided that a discharge current can flow out of buffer capacitor 33 to supply connection 30.

The sensors 23, 24 of sensor unit 21 can be configured as parameter-dependent resistors. In the embodiment the resistance value of sensors 23, 24 changes depending on the temperature. Thereby the resistance value can increase or decrease depending on the temperature. Thus, the measured voltage UM changes depending on the resistance value of the first sensor 23, for example, if the first output current I1 flows through first sensor 23 or depending on the resistance value of second sensor 24, if second output current I2 flows through the second sensor 24.

If instead of the temperature another parameter shall be detected, also sensors 23, 24 can be used, the resistance values of which change depending on the respective parameter to be detected, for example depending on the humidity in the surrounding atmosphere, etc.

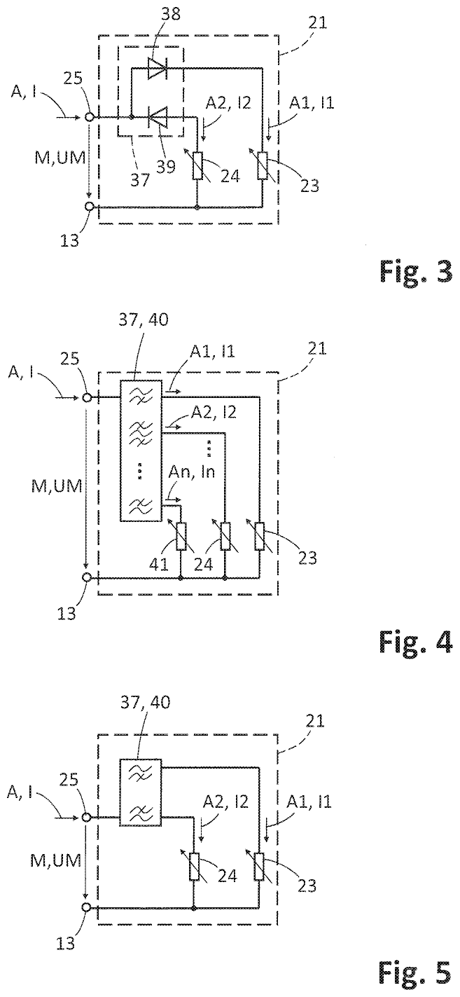

A block diagram of an embodiment of sensor unit 21 is illustrated in FIG. 3, which is particularly expedient in embodiments in which the sensor unit 21 comprises exactly two sensors 23, 24. In this embodiment coupling device 37 has a first diode 38, which is connected in series to the first sensor 23 and a second diode 39, which is connected in series to the second sensor 24. These two series connections are connected in parallel to one another between measuring line 25 and control line 13. The cathode of first diode 38 is thereby connected with first sensor 23, while in the other series connection the anode of second diode 39 is connected with second sensor 24. Depending on the polarity of the output signal A, therefore only one of the diodes 38, 39 is conductive, while the other diode 39 or 38 blocks. In this embodiment the coupling device 37 transmits the output signal A depending on its polarity (used as characteristic according to the example) either as first output signal A1 to the first sensor 23 or as second output signal A2 to the second sensor 24. The output signal A or the output current I having changing polarity is illustrated in FIG. 7 by way of example. Thus, first sensor 23 is active during the positive components of output signal A, second sensor 24 is active during the negative components of output signal A. At each point in time the measured voltage UM, therefore, characterizes the temperature detected by first sensor 23 (positive components of output signal A) or the temperature detected by second sensor 24 (negative components of output signal A).

This embodiment of sensor unit 21 or coupling device 37, therefore, allows the selection or use of either first sensor 23 or second sensor 24 for temperature detection in a simple manner.

In the embodiment according to FIG. 3, coupling device 37 comprises exclusively passive components, namely diodes 38, 39. It is preferred, if coupling device 37 is realized without active components, i.e. without controllable and/or amplifying components, in order to guarantee a simple configuration and simple function of measuring assembly 20.

Additional embodiments of sensor unit 21 having multiple sensors are illustrated in FIGS. 4 and 5 by way of example. Also, in these sensor units 21 coupling device 37 can be exclusively realized with passive components.

In the embodiments according to FIGS. 4 and 5, coupling device 37 comprises a crossover network 40 or is formed by means of crossover network 40. The coupling device 37 is configured in this manner to transmit the output signal A to one of the outputs of the coupling device 37 and thus, according to the example, to one of the connected sensors, depending on the frequency of the output signal A as characteristic feature of the output signal A. Depending on the configuration of the crossover network 40, hereby a number n of sensors can be controlled via n outputs of coupling device 37 individually, as schematically illustrated in FIG. 4. In addition to first sensor 23 and second sensor 24, therefore, at least one additional sensor 41 can be used. Due to crossover network 40, output signal A is either transmitted as first output signal A1 to the first sensor 23, as second output signal A2 to the second sensor 24 or as at least one additional output signal An to one of the additional sensors 41. The number of selectable and usable sensors 23, 24, 41 depends on the fineness of graduation of crossover network 40.

The crossover network 40 can be realized by frequency filters, for example at least one high pass, at least one band pass, at least one low pass or an arbitrary combination thereof.

In FIG. 5 a simple realization possibility of sensor unit 21 according to FIG. 4 is illustrated, if only a first sensor 23 and a second sensor 24 are present. In this case, the crossover network 40 of coupling device 37 can be simply realized by means of a high pass and a low pass (FIG. 5).

In FIG. 8 a temporal progress of an output signal A or an output current I is illustrated schematically by way of example, having a periodic progress that in the preferred embodiment has only one polarity at each point in time. Thereby the frequency or period of output signal A may change and may be switched between a first frequency f1 and a second frequency f2. For example, output signal A can be used for use of sensor unit 21 according to FIG. 5. If more than two individually selectable sensors (number n) are present (FIG. 4), output signal A according to FIG. 8 can be switched between a number n of different frequencies, f1, f2, . . . fn.

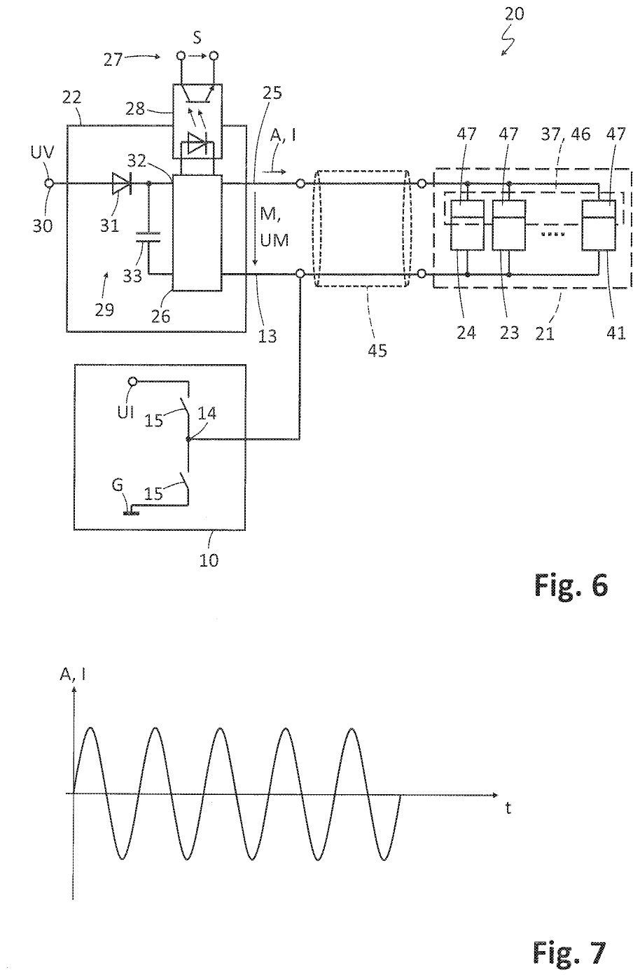

Another embodiment for a measuring assembly 20 is schematically illustrated in FIG. 6. There, measuring line 25 and control line 13 form a common bus line 45 according to a defined standard, for example I²C-standard. The coupling device 37 in this embodiment is formed by a filter arrangement 46, wherein filter arrangement 46 comprises one filter 47 respectively that is arranged in series to one of the individually controllable sensors 23, 24, 41 respectively. Also, in this embodiment any number of sensors (number n) can be individually controlled via bus line 45 in principle.

The present disclosure refers to a measuring assembly for measuring a parameter on an electrical device 11, particularly an electric motor 12. The electrical device 11 is controlled by means of an inverter circuit 10. The measuring assembly 20 comprises a measuring circuit 22 that is electrically connected with a sensor unit 21 comprising at least one sensor 23, 24 via a measuring line 25. The measuring circuit 22 is in addition connected with a control line 13, which connects the electrical device 11 with an inverter output 14 of inverter circuit 10. At least two different inverter output potentials can be applied to control line 13 depending on the switching condition of the inverter output 14 or the inverter circuit 10. The measuring circuit 22 is configured to transmit an output signal A to the sensor unit 21 and to detect an electrical measured parameter M at measuring line 25 and/or at control line 13. The electrical measured parameter M is influenced based on the received output signal A by sensor unit 21 depending on the parameter to be detected, for example the temperature. For example, the sensors 23, 24, 41 can comprise a parameter-dependent resistor for this purpose.

### LIST OF REFERENCE SIGNS

10 inverter circuit
11 electrical device
12 electric motor
12u motor phase of electric motor
12v motor phase of electric motor
12w motor phase of electric motor
13 control line
14 inverter output
15 inverter switch
20 measuring assembly
21 sensor unit
22 measuring circuit
23 first sensor
24 second sensor
25 measuring line
26 evaluation unit
27 measuring output
28 optocoupler
29 bootstrap voltage supply
30 supply connection
31 input diode
32 input of evaluation unit
33 buffer capacitor
37 coupling device
38 first diode
39 second diode
40 crossover network
41 additional sensor
45 bus line
46 filter arrangement
47 filter
A output signal
A1 first output signal
A2 second output signal
An additional output signal
f1 first frequency of output signal
f2 second frequency of output signal
G ground
I output current
I1 first output current
I2 second output current
M measured parameter
S measuring signal
t Time
T1 first period of output signal
T2 second period of output signal
UI inverter voltage
UM measured voltage
UV supply voltage

1. A measuring assembly for an electrical device that is controlled by means of an inverter circuit, comprising:
a control line connected with an inverter output of inverter circuit, at which an inverter output potential applies, which is predefined by the inverter circuit,
a measuring circuit that is connected with a sensor unit via a measuring line and in addition with the control line and that is configured to transmit an output signal via the measuring line to the sensor unit and that is in addition configured to detect an electrical measured parameter at the measuring line and/or the control line,
wherein the sensor unit comprises at least one sensor, which is configured for arrangement on or in the electrical device, wherein the at least one sensor is arranged in an electrical path between the measuring line and the control line and is configured to influence the output signal depending on a parameter to be measured.

2. The measuring assembly according to claim 1, wherein the sensor unit comprises at least two sensors and a coupling device, wherein the coupling device is arranged in the electrical path between the at least two sensors and the measuring line and is configured to allow a transmission of the output signal to one of the at least two sensors depending on a characteristic of the output signal.

3. The measuring assembly according to claim 2, wherein the coupling device exclusively comprises passive components.

4. The measuring assembly according to claim 2, wherein the sensor unit comprises a first sensor and a second sensor, wherein the coupling device comprises a first blockable component and a second blockable component, wherein a first series connection comprising the first blockable component and the first sensor and a second series connection comprising the second blockable component and the second sensor are connected in parallel to one another between the measuring line and the control line.

5. The measuring assembly according to claim 4, wherein the first blockable component is a first diode and the second blockable component is a second diode, which are connected anti-parallel to one another and wherein the measuring circuit is configured to produce the output signal so that it comprises different polarities.

6. The measuring assembly according to claim 2, wherein the coupling device comprises a crossover network.

7. The measuring assembly according to claim 6, wherein the measuring circuit is configured to produce the output signal so that it comprises different frequencies.

8. The measuring assembly according to claim 2, wherein the coupling device comprises a filter arrangement.

9. The measuring assembly according to claim 8, wherein the measuring line and the control line are part of a bus line to which the at least two sensors are connected via the filter arrangement.

10. The measuring assembly according to claim 1, wherein the measuring circuit comprises a bootstrap voltage supply, which is connected with the control line.

11. The measuring assembly according to claim 1, wherein the measuring circuit comprises a measuring output and wherein the measuring circuit is configured to produce a measuring signal based on the measured parameter and to provide it at the measuring output.

12. The measuring assembly according to claim 11, wherein the measuring signal is with regard to the potential independent from the inverter output potential of the control line.

13. The measuring assembly according to claim 11, wherein the measuring output is galvanically separated from the control line and/or the measuring line.

14. The measuring assembly according to claim 11, wherein the measuring output is configured as blank transistor output.

15. The measuring assembly according to claim 1, wherein the at least one sensor comprises a resistor that is configured to change its resistance value depending on the parameter to be measured.

16. The measuring assembly according to claim 3, wherein the sensor unit comprises a first sensor and a second sensor, wherein the coupling device comprises a first blockable component and a second blockable component, wherein a first series connection comprising the first blockable component and the first sensor and a second series connection comprising the second blockable component and the second sensor are connected in parallel to one another between the measuring line and the control line.

17. The measuring assembly according to claim 16, wherein the first blockable component is a first diode and the second blockable component is a second diode, which are connected anti-parallel to one another and wherein the measuring circuit is configured to produce the output signal so that it comprises different polarities.

18. The measuring assembly according to claim 3, wherein the coupling device comprises a crossover network.

19. The measuring assembly according to claim 18, wherein the measuring circuit is configured to produce the output signal so that it comprises different frequencies.

20. The measuring assembly according to claim 3, wherein the coupling device comprises a filter arrangement.
